(19) United States
(12) Patent Application Publication
(10) Pub. No.: US 2026/0096105 A1
(43) Pub. Date: Apr. 2, 2026

(54) SEMICONDUCTOR MEMORY DEVICE

(71) Applicant: SAMSUNG ELECTRONICS CO., LTD., Suwon-si (KR)

(72) Inventors: HYUNSUNG JUNG, Suwon-si (KR); Jihun BYUN, Suwon-si (KR)

(73) Assignee: SAMSUNG ELECTRONICS CO., LTD., Suwon-si (KR)

(21) Appl. No.: 19/226,735

(22) Filed: Jun. 3, 2025

(30) Foreign Application Priority Data
Sep. 27, 2024 (KR) 10-2024-0131869

(51) Int. Cl. H10B 61/00; H10N 50/01; H10N 50/10

(52) U.S. Cl. CPC H10B 61/10; H10N 50/01; H10N 50/10

(57) ABSTRACT

Provided is a semiconductor memory device including a substrate, an interlayer insulating layer on the substrate, lower contact plugs penetrating the interlayer insulating layer, magnetic tunnel junction patterns on the lower contact plugs, respectively, lower electrodes between the lower contact plugs and the magnetic tunnel junction patterns, respectively, a buffer insulating layer between the lower electrodes and on the interlayer insulating layer, a capping insulating layer on a sidewall of each of the magnetic tunnel junction patterns and an upper surface of the buffer insulating layer, and upper electrodes on the magnetic tunnel junction patterns, respectively.

### CROSS-REFERENCE TO RELATED APPLICATIONS

This application claims priority to Korean Patent Application No. 10-2024-0131869 filed on Sep. 27, 2024, in the Korean Intellectual Property Office, the disclosure of which is hereby incorporated by reference in its entirety.

### BACKGROUND

### 1. Field

Embodiments of the present disclosure relate to a semiconductor memory device, and more specifically, relates to a semiconductor memory device including a magnetic tunnel junction.

### 2. Description of Related Art

As electronic devices operate at higher speed while consuming lower amount of power, there is a demand for the semiconductor memory device having higher-speed and/or consuming lower amount of power in the electronic devices. To satisfy these demands, magnetic memory devices have been developed as the semiconductor memory devices. The magnetic memory devices are spotlighted as next-generation semiconductor memory devices because of their potential of high-speed and/or non-volatile characteristics.

In particular, as tunnel magnetoresistance (TMR) effect in a magnetic tunnel junction (MTJ) is attracting attention as a data storage mechanism in magnetic memory devices, magnetic memory devices having the magnetic tunnel junction have been actively studied recently. Furthermore, with the demand for high integration and/or low power consumption of magnetic memory devices, many studies are being conducted to meet the demands.

### SUMMARY

One or more embodiments provide a semiconductor memory device with improved integration and process margin and a method of manufacturing the same.

According to an aspect of one or more embodiments, there is provided a semiconductor memory device including a substrate, an interlayer insulating layer on the substrate, lower contact plugs penetrating the interlayer insulating layer, magnetic tunnel junction patterns on the lower contact plugs, respectively, lower electrodes between the lower contact plugs and the magnetic tunnel junction patterns, respectively, a buffer insulating layer between the lower electrodes and on the interlayer insulating layer, a capping insulating layer on a sidewall of each of the magnetic tunnel junction patterns and an upper surface of the buffer insulating layer, and upper electrodes on the magnetic tunnel junction patterns, respectively.

According to another aspect of one or more embodiments, there is provided a semiconductor memory device including a substrate, an interlayer insulating layer, a lower contact plug penetrating the interlayer insulating layer, a magnetic tunnel junction pattern connected to the lower contact plug, a lower electrode between the lower contact plug and the magnetic tunnel junction pattern, and an upper electrode on the magnetic tunnel junction pattern, wherein a first sidewall of the lower electrode is aligned with a sidewall of the lower contact plug and is spaced part from a sidewall of the magnetic tunnel junction pattern.

According to still another aspect of one or more embodiments, there is provided a semiconductor memory device including a substrate, lower wiring lines on the substrate, an interlayer insulating layer on the lower wiring lines, lower contact plugs penetrating the interlayer insulating layer, magnetic tunnel junction patterns on the lower contact plugs, respectively, lower electrodes between the lower contact plugs and the magnetic tunnel junction patterns, respectively, a buffer insulating layer between the lower electrodes on the interlayer insulating layer, upper electrodes on the magnetic tunnel junction patterns, respectively, a capping insulating layer on a sidewall of each of the magnetic tunnel junction patterns and an upper surface of the buffer insulating layer, a buried insulating layer on the magnetic tunnel junction patterns on the capping insulating layer, and bit lines penetrating the buried insulating layer and connected to the upper electrodes, wherein the capping insulating layer is spaced apart from an upper surface of the interlayer insulating layer.

### BRIEF DESCRIPTION OF DRAWINGS

Embodiments will be more clearly understood from the following detailed description taken in conjunction with the accompanying drawings in which:

FIG. 1 illustrates a memory cell array of a semiconductor memory device according to one or more embodiments;

FIG. 2 illustrates a unit memory cell of a semiconductor memory device according to one or more embodiments;

FIG. 3 is a plan view of a semiconductor memory device according to one or more embodiments;

FIG. 4 is a cross-sectional view of a semiconductor memory device according to one or more embodiments, illustrating a cross-section taken along line I-I′ of FIG. 3;

FIGS. 5, 6, 7, and 8 are enlarged views of a portion of a semiconductor memory device according to various embodiments, illustrating an enlarged view of portion ‘P1’ of FIG. 4;

FIGS. 9A and 9B are drawings illustrating a magnetic tunnel junction pattern of a semiconductor memory device according to one or more embodiments;

FIGS. 10A, 10B, 10C, 10D, 10E, 10F, 10G, 10H, 10I, and 10J are sectional views taken along line I-I′ of FIG. 3 to illustrate a method of manufacturing a semiconductor memory device according to one or more embodiments.

FIGS. 11A, 11B, 11C, and 11D are sectional views taken long line I-I′ of FIG. 3 to illustrate a method of manufacturing a semiconductor memory device according to one or more embodiments.

### DETAILED DESCRIPTION

Hereinafter, a semiconductor memory device according to one or more embodiments will be described in detail with reference to the drawings.

It will be understood that, although the terms first, second, third, fourth, etc. may be used herein to describe various elements, components, regions, layers and/or sections (collectively “elements”), these elements should not be limited by these terms. These terms are only used to distinguish one element from another element. Thus, a first element described in this description section may be termed a second element or vice versa in the claim section without departing from the teachings of the disclosure.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

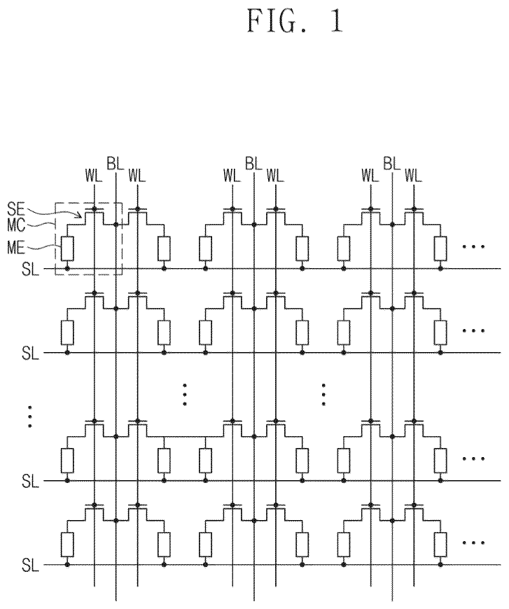

FIG. 1 illustrates a cell array of a semiconductor memory device according to one or more embodiments.

Referring to FIG. 1, a plurality of unit memory cells MC may be two-dimensionally or three-dimensionally arranged. Each of the unit memory cells MC may be connected between a word line WL and a bit line BL which intersect each other. Each of the unit memory cells MC may include a memory element ME and a selection element SE. The selection element SE and the memory element ME may be electrically connected in series to each other.

The memory element ME may be connected between the bit line BL and the selection element SE, and the selection element SE may be connected between the memory element ME and a source line SL. The selection element SE may be controlled by the word line WL. The memory element ME may be a variable resistance element of which a resistance is changeable between two resistance states by an electrical pulse applied thereto. In one or more embodiments, the memory element ME may have a relatively thin layer structure of which an electrical resistance is changed using spin torque transferred by a current passing through the memory element ME. The memory element ME may have a relatively thin layer structure illustrating a magnetoresistance property and may include, for example, at least one ferromagnetic material and/or at least one anti-ferromagnetic material.

The selection element SE may selectively control the supply of a current to the memory element ME on the base of a voltage of the word line WL. The selection element SE may be a diode, a PNP bipolar transistor, an NPN bipolar transistor, an NMOS field effect transistor, and a PMOS field effect transistor. For example, when the selection element SE is the bipolar transistor or MOS field effect transistor corresponding to a three-terminal element, the memory cell array may further include the source line SL connected to a source electrode of the transistor. The source line SL may be disposed between the word lines WL adjacent to each other, and two transistors may share one source line SL.

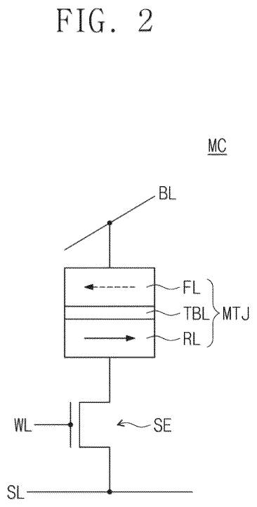

FIG. 2 is a diagram illustrating a unit memory cell of a semiconductor memory device according to one or more embodiments.

Referring to FIG. 2, a unit memory cell MC may include a memory element ME and a selection element SE. In one or more embodiments, the selection element SE may be a MOS field effect transistor, and the memory element ME may include a magnetic tunnel junction MTJ. The magnetic tunnel junction MTJ may be connected between a bit line BL and the selection element SE, and the selection element SE may be connected between the magnetic tunnel junction MTJ and a source line SL and may be controlled by the word line WL.

The magnetic tunnel junction MTJ may include a plurality of magnetic layers FL and RL and a tunnel barrier layer TBL between the magnetic layers FL and RL. One RL of the magnetic layers FL and RL may be a reference layer having a fixed magnetization direction regardless of an external magnetic field or spin transfer torque under a normal use environment. The other one FL of the magnetic layers FL and RL may be a free layer whose magnetization direction is freely changed by an external magnetic field.

The magnetic tunnel junction MTJ may store data in a unit memory cell MC by utilizing a difference in electrical resistance depending on a magnetization direction of the magnetic layers FL and RL. The electrical resistance of the magnetic tunnel junction MTJ may be adjusted by changing the magnetization direction of the free layer FL. In addition, the electrical resistance of the magnetic tunnel junction MTJ may be much greater when magnetization directions of the reference layer RL and the free layer FL are antiparallel than when magnetization directions of the reference layer RL and the free layer FL are parallel.

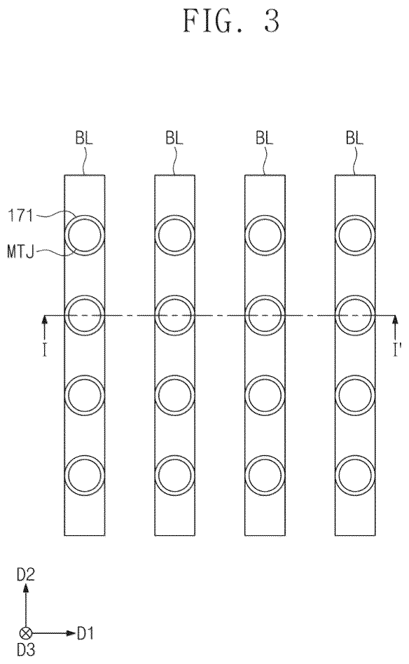

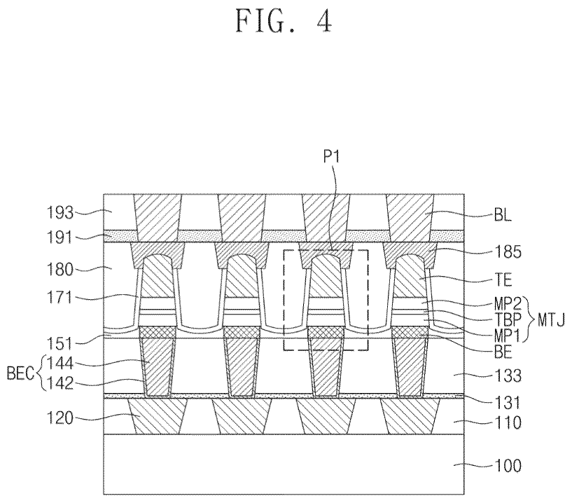

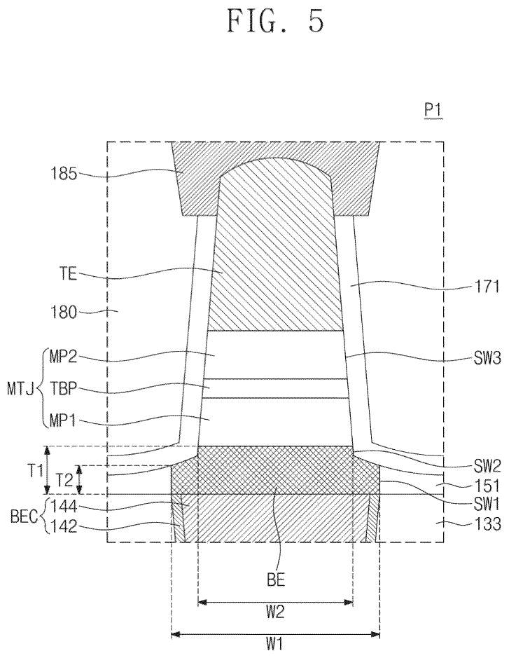

FIG. 3 is a plan view of a semiconductor memory device according to one or more embodiments. FIG. 4 is a cross-sectional view of a semiconductor memory device according to one or more embodiments, illustrating a cross-section taken along line I-I′ of FIG. 3. FIGS. 5, 6, 7, and 8 are enlarged views of a portion of a semiconductor memory device according to various embodiments, illustrating an enlarged view of portion ‘P1’ of FIG. 4.

Referring to FIGS. 3 and 4, a first interlayer insulating layer 110 may be disposed on a substrate 100. The substrate 100 may be a silicon substrate, a germanium substrate, and/or a silicon-germanium substrate.

Selection transistors may be provided as selection elements SE (refer to FIG. 2) described with reference to FIG. 2 on the substrate 100, and the first interlayer insulating layer 110 may be provided on and cover the selection transistors.

The first interlayer insulating layer 110 may be formed as a single layer or multiple layers including oxide, nitride, and/or oxynitride. The first interlayer insulating layer 110 may include an insulating material. For example, the first interlayer insulating layer 110 may be formed of an HDP oxide layer, a TEOS layer, a PE-TEOS layer, a USG layer, a BSG layer, a PSG layer, a BPSG layer, a SOG layer, a TOSZ layer, or a combination thereof.

Lower wiring lines 120 may be provided in the first interlayer insulating layer 110. The lower wiring lines 120 may be electrically connected to selection transistors. The lower wiring lines 120 may be vertically stacked in the first interlayer insulating layer 110. The lower wiring lines 120 may include a via portion and a wiring portion.

The lower wiring lines 120 may include, for example, copper (Cu) or a copper alloy. Here, the copper alloy refers to a copper alloy in which a small amount of carbon (C), silver (Ag), cobalt (Co), tantalum (Ta), indium (In), tin (Sn), zinc (Zn), manganese (Mn), titanium (Ti), magnesium (Mg), chromium (Cr), germanium (Ge), strontium (Sr), platinum (Pt), magnesium (Mg), aluminum (Al) or zirconium (Zr) is mixed. As another example, the lower wiring lines 120 may include, for example, a metal such as tungsten (W), titanium, and tantalum and/or a conductive metal nitride such as titanium nitride, tantalum nitride, and tungsten nitride.

A diffusion barrier layer 131 may be disposed on upper surfaces of the lower wiring lines 120 and the first interlayer insulating layer 110. The diffusion barrier layer 131 may be, for example, silicon nitride (SiN), silicon oxynitride (SiON), silicon carbide (SiC), silicon carbon nitride (SiCN), and combinations thereof.

A second interlayer insulating layer 133 may be stacked on the diffusion barrier layer 131. The second interlayer insulating layer 133 may be formed of a HDP oxide layer, a TEOS layer, a PE-TEOS layer, a USG layer, a BSG layer, a PSG layer, a BPSG layer, a SOG layer, a TOSZ layer, or a combination thereof. As another example, the second interlayer insulating layer 133 may be formed of a dielectric material having a dielectric constant that is smaller than a dielectric constant of a silicon oxide layer.

Lower contact plugs BEC may penetrate the second interlayer insulating layer 133 and be electrically connected to the lower wiring lines 120, respectively. A plurality of insulating layers, contact plugs, and wiring lines may be further included between the lower contact plugs BEC and the lower wiring lines 120.

Upper surfaces of the lower contact plugs BEC may be substantially coplanar with an upper surface of the second interlayer insulating layer 133. The lower contact plugs BEC may include a different metal material from that of the lower wiring lines 120. The lower contact plugs BEC may include a metal such as tungsten, titanium, and tantalum and/or a conductive metal nitride such as titanium nitride (TiN), tantalum nitride (TaN), and tungsten nitride (WN), for example.

For example, each of the lower contact plugs BEC may include a barrier metal pattern 142 and a metal pattern 144. The barrier metal pattern 142 may be provided on and cover a lower surface and sidewalls of the metal pattern 144 with a uniform thickness. The barrier metal pattern 142 may include a conductive metal nitride such as TiN, TaN, and WN, and the metal pattern 144 may include a metal such as tungsten, titanium, tantalum, and copper.

A lower electrode BE, a magnetic tunnel junction pattern MTJ, and an upper electrode TE may be sequentially stacked on each of the lower contact plugs BEC.

The lower electrode BE may be interposed between the lower contact plug BEC and the magnetic tunnel junction pattern MTJ, respectively. The lower electrode BE may include, for example, a metal such as Pt, W, Co, ruthenium (Ru), palladium (Pd), iridium (Ir), or Ag. As another example, the lower electrode BE may include a metal such as tungsten, titanium, and tantalum and/or a conductive metal nitride such as TiN, TaN, and WN.

For example, referring to FIG. 5, the lower electrode BE may be in direct contact with the upper surface of the lower contact plug BEC and may be in direct contact with a lower surface of the magnetic tunnel junction pattern MTJ.

The lower electrode BE may have a first width W1 at the lower surface in contact with the upper surface of the lower contact plug BEC and a second width W2 smaller than the first width W1 at the upper surface in contact with the lower surface of the magnetic tunnel junction pattern MTJ. For example, the first width W1 of the lower electrode BE may be substantially the same as the width on the upper surface of the lower contact plug BEC.

The lower electrode BE may include an upper portion in contact with the magnetic tunnel junction pattern MTJ and a lower portion in contact with the lower contact plug BEC. A lower portion of the lower electrode BE may have a first sidewall SW1 aligned with a sidewall of the lower contact plug BEC. An upper portion of the lower electrode BE may have a second sidewall SW2 aligned with a sidewall SW3 of the magnetic tunnel junction pattern MTJ. For example, the second sidewall SW2 of the lower electrode BE may be aligned with a sidewall of a first magnetic pattern MP1 of the magnetic tunnel junction pattern MTJ. For example, the second sidewall SW2 of the lower electrode BE may be disposed to be misaligned with the first sidewall SW1. For example, the first sidewall SW1 of the lower electrode BE may be misaligned with the sidewall SW3 of the magnetic tunnel junction pattern MTJ. For example, the second sidewall SW2 of the lower electrode BE may be spaced apart from the first sidewall SW1 and the first sidewall SW1 of the lower electrode BE may be spaced apart from the sidewall SW3 of the magnetic tunnel junction pattern MTJ.

The lower electrode BE may have a first thickness T1 at a center of the lower electrode BE and a second thickness T2 smaller than the first thickness T1 at an edge of the lower electrode BE.

According to one or more embodiments, a buffer insulating layer 151 may be disposed between the lower electrodes BE on the second interlayer insulating layer 133.

The buffer insulating layer 151 may be in direct contact with the sidewalls of the lower electrodes BE. An upper surface of the buffer insulating layer 151 may be positioned at a level between the upper surfaces and the lower surfaces of the lower electrodes BE. The upper surface of the buffer insulating layer 151 may be rounded (curved) as illustrated in FIGS. 4 and 5.

The buffer insulating layer 151 may include an insulating material different from an insulating material of the second interlayer insulating layer 133. According to one or more embodiments, the buffer insulating layer 151 may be formed of a metal oxide including a metal element and oxygen. For example, the buffer insulating layer 151 may include zinc oxide (ZnO), aluminum oxide (Al₂O₃), hafnium oxide (HfO₂), titanium oxide (TiO₂), or zirconium oxide ZrO₂.

The magnetic tunnel junction pattern MTJ may be disposed on the lower electrode BE. A lower surface of the magnetic tunnel junction pattern MTJ may be in direct contact with the upper surface of the lower electrode BE.

For example, referring to FIG. 5, a lower width of the magnetic tunnel junction pattern MTJ may be smaller than a first width W1 of the lower electrode BE. In addition, an upper width of the magnetic tunnel junction pattern MTJ may be smaller than the lower width of the magnetic tunnel junction pattern MTJ. The magnetic tunnel junction pattern MTJ may have a sidewall SW3 inclined with respect to the upper surface of the substrate 100, and the sidewall SW3 of the magnetic tunnel junction pattern MTJ may be arranged to be misaligned with the first sidewall SW1 of the lower electrode BE. For example, the sidewall SW3 of the magnetic tunnel junction pattern MTJ may be spaced apart from the first sidewall SW1 of the lower electrode BE

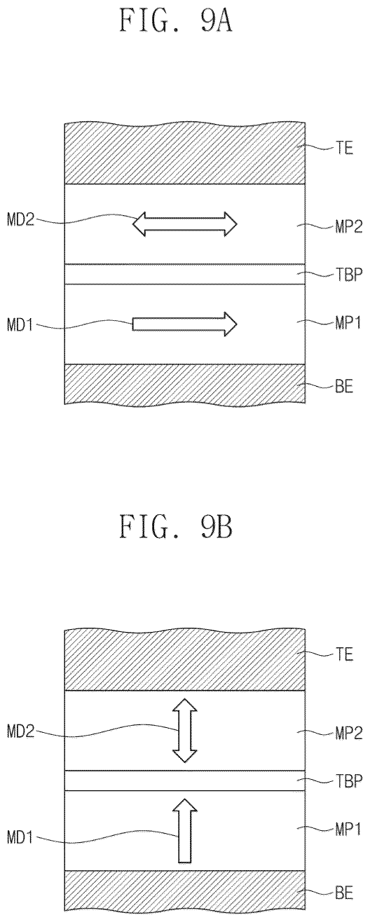

The magnetic tunnel junction pattern MTJ may include a first magnetic pattern MP1, a second magnetic pattern MP2, and a tunnel barrier pattern TBP therebetween. The first magnetic pattern MP1 may be disposed between the lower electrode BE and the tunnel barrier pattern TBP, and the second magnetic pattern MP2 may be disposed between the upper electrode TE and the tunnel barrier pattern TBP. The magnetic tunnel junction pattern MTJ will be described in more detail later with reference to FIGS. 9A and 9B.

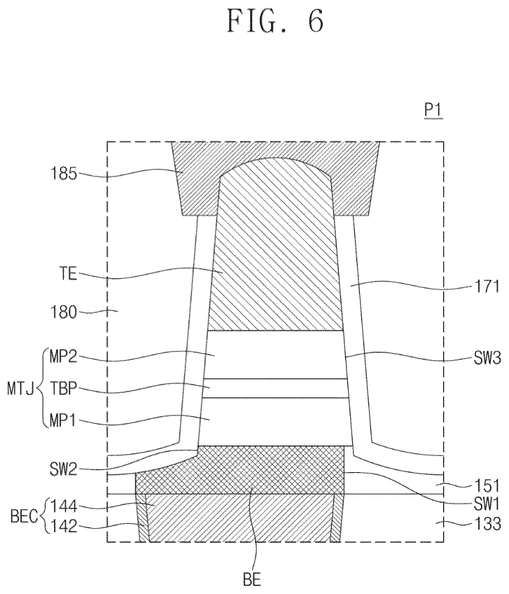

According to one or more embodiments, the magnetic tunnel junction pattern MTJ may be misaligned and disposed on the lower electrode BE, as illustrated in FIG. 6. In this example, a portion of the lower surface of the magnetic tunnel junction pattern MTJ may be in contact with the buffer insulating layer 151.

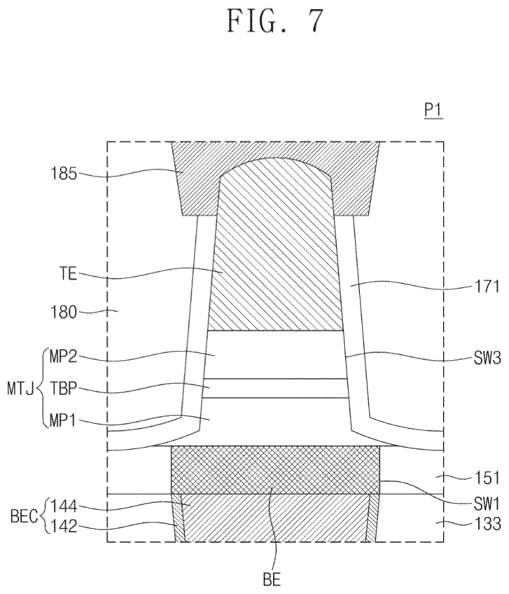

As another example, a lower width of the magnetic tunnel junction pattern MTJ may be greater than the first width W1 of the lower electrode BE, as illustrated in FIG. 7. In this example, an entire upper surface of the lower electrode BE may be in contact with a portion of the lower surface of the magnetic tunnel junction pattern MTJ.

Referring to FIGS. 4 and 5, the upper electrode TE may be interposed between a conductive contact 185 and the magnetic tunnel junction pattern MTJ. The upper electrode TE may include at least one of a non-magnetic metal such as tungsten, titanium, tantalum, and ruthenium, and a metal nitride such as TiN, WN, and TaN. For example, the upper electrode TE may include the same metal nitride as a material of the lower electrode BE. A thickness of the upper electrode TE may be greater than a thickness of the lower electrode BE. The sidewall of the upper electrode TE may be aligned with the sidewall SW3 of the magnetic tunnel junction pattern MTJ.

Referring to FIGS. 4 and 5, a capping insulating layer 171 may be provided on and cover upper surfaces of the buffer insulating layer 151 and the sidewalls of the magnetic tunnel junction patterns MTJ with a uniform thickness. The capping insulating layer 171 may extend continuously from the sidewalls of the magnetic tunnel junction patterns MTJ to the sidewalls of the upper electrodes TE. The capping insulating layer 171 may be in direct contact with portions of the sidewalls of the upper electrodes TE.

The capping insulating layer 171 may be formed of an insulating material having etching selectivity with respect to the buffer insulating layer 151 and a buried insulating layer 180. For example, the capping insulating layer 171 may be formed of SiN, SiON, SiC, SiCN, and combinations thereof.

For example, referring to FIG. 5, the capping insulating layer 171 may be provided on and cover the upper surface of the buffer insulating layer 151 disposed between the lower electrodes BE with a uniform thickness. The capping insulating layer 171 may be vertically spaced apart from the second interlayer insulating layer 133 by the buffer insulating layer 151. A lower surface of the capping insulating layer 171 may be positioned at a level between the upper surface and the lower surface of the lower electrode BE. The capping insulating layer 171 may extend onto a portion of the lower electrode BE on the sidewalls of the magnetic tunnel junction patterns MTJ.

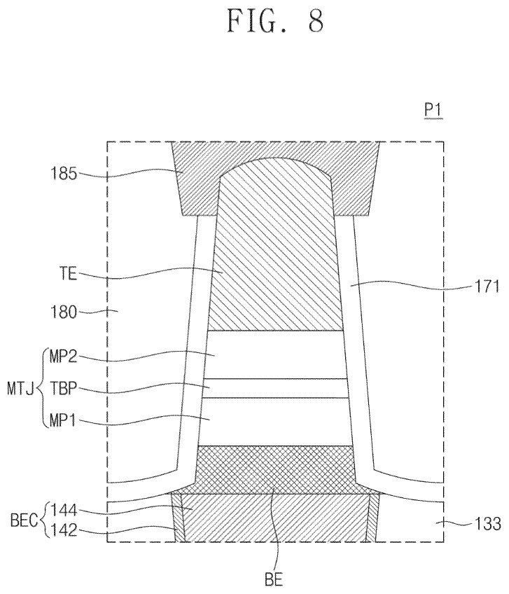

Referring to FIG. 7, the capping insulating layer 171 may be spaced from the lower electrode BE. In one or more embodiments, the capping insulating layer 171 may be in contact with a portion of the second interlayer insulating layer 133, as illustrated in FIG. 8.

Referring again to FIGS. 3 and 4, a buried insulating layer 180 may fill a portion between the magnetic tunnel junction patterns MTJ on the capping insulating layer 171. The buried insulating layer 180 may include, for example, silicon oxide (SiO₂), SiN, SiON, or a low-k dielectric material having a dielectric constant smaller than a dielectric constant of silicon oxide. The buried insulating layer 180 may be formed of a single layer or a multilayer layer.

Conductor contacts 185 may be provided on the upper electrodes TE, respectively. The conductive contacts 185 may penetrate a portion of the buried insulating layer 180 and the capping insulating layer 171 and be connected to the upper electrodes TE, respectively. Each of the conductive contacts 185 may be in direct contact with the upper surface of the upper electrode TE. Each of the conductive contacts 185 may have a lower width greater than the upper width of the upper electrode TE.

The conductive contacts 185 may include a metal (e.g., copper) and a conductive metal nitride (e.g., titanium nitride, tantalum nitride, and/or tungsten nitride, etc.).

An etching stop layer 191 and a mold layer 193 may be sequentially stacked on the buried insulating layer 180.

The etching stop layer 191 may be provided on and cover the upper surfaces of the conductive contacts 185 and the upper surface of the buried insulating layer 180. The etching stop layer 191 may be formed of an insulating material having etch selectivity with respect to the mold layer 193, for example, SiN, SiON, SiC, SiCN, and combinations thereof. The mold layer 193 may be formed of, for example, silicon oxide or a low-k dielectric material having a lower dielectric constant than silicon oxide.

Bit lines BL may be formed in the etching stop layer 191 and the mold layer 193. The bit lines BL may extend in a second direction D2 and may be spaced apart from each other in a first direction D1. Each of the bit lines BL may be commonly connected to magnetic tunnel junction patterns MTJ arranged in the second direction D2.

The bit lines BL may include, for example, Cu or a Cu alloy. Here, the Cu alloy refers to copper mixed with a relatively small amount of C, Ag, Co, Ta, In, Sn, Zn, Mn, Ti, Mg, Cr, Ge, Sr, Pt, Mg, Al, or Zr. As another example, the bit lines BL may include, for example, a metal such as W, Ti, and Ta, and/or a conductive metal nitride such as TiN, TaN, and WN.

FIGS. 9A and 9B are drawings illustrating a magnetic tunnel junction pattern of a semiconductor memory device according to one or more embodiments.

Referring to FIGS. 3, 9A, and 9B, a magnetic tunnel junction pattern MTJ may be interposed between a lower electrode BE and an upper electrode TE. The magnetic tunnel junction pattern MTJ may include a first magnetic pattern MP1, a second magnetic pattern MP2, and a tunnel barrier pattern TBP between the first magnetic pattern MP1 and the second magnetic pattern MP2.

The first magnetic pattern MP1 may be a reference layer, whose magnetization direction MD1 is fixed to a specific direction, and the second magnetic pattern MP2 may be a free layer, whose magnetization direction MD2 is capable of being changed to be parallel or antiparallel to the magnetization direction MD1 of the first magnetic pattern MP1. FIGS. 9A and 9B illustrate an example, in which the second magnetic pattern MP2 is used as a free layer, but embodiments are not limited thereto. As another example, the first magnetic pattern MP1 may be a free layer and the second magnetic pattern MP2 may be a reference layer.

For example, referring to FIG. 9A, the magnetization directions MD1 and MD2 of the first and second magnetic patterns MP1 and MP2 may be perpendicular to an interface between the tunnel barrier pattern TBP and the second magnetic pattern MP2. In this example, each of the first and second magnetic patterns MP1 and MP2 may include at least one of perpendicular magnetic materials (e.g., CoFeTb, CoFeGd, and CoFeDy), perpendicular magnetic materials with L₁₀ structure, CoPt-based materials with hexagonal-close-packed structure, and perpendicular magnetic structures. The perpendicular magnetic material with the L₁₀ structure may include at least one of L₁₀ FePt, L₁₀ FePd, L₁₀ CoPd, or L₁₀ CoPt. The perpendicular magnetic structures may include magnetic layers and non-magnetic layers that are alternately and repeatedly stacked. For example, the perpendicular magnetic structures may include at least one of (Co/Pt)n, (CoFe/Pt)n, (CoFe/Pd)n, (Co/Pd)n, (Co/Ni)n, (CoNi/Pt)n, (CoCr/Pt)n, or (CoCr/Pd)n, where ‘n’ denotes the number of stacked layers.

As another example, referring to FIG. 9B, the magnetization directions MD1 and MD2 of the first and second magnetic patterns MP1 and MP2 may be parallel to the interface between the tunnel barrier pattern TBP and the second magnetic pattern MP2. In this example, each of the first and second magnetic patterns MP1 and MP2 may include a ferromagnetic material. The first magnetic pattern MP1 may further include an anti-ferromagnetic material, which is provided in the first magnetic pattern MP1 and is used to fix a magnetization direction of the ferromagnetic material.

The tunnel barrier pattern TBP may include at least one of a Mg oxide layer, a Ti oxide layer, an Al oxide layer, a Mg—Zn oxide layer, or a Mg—B oxide layer.

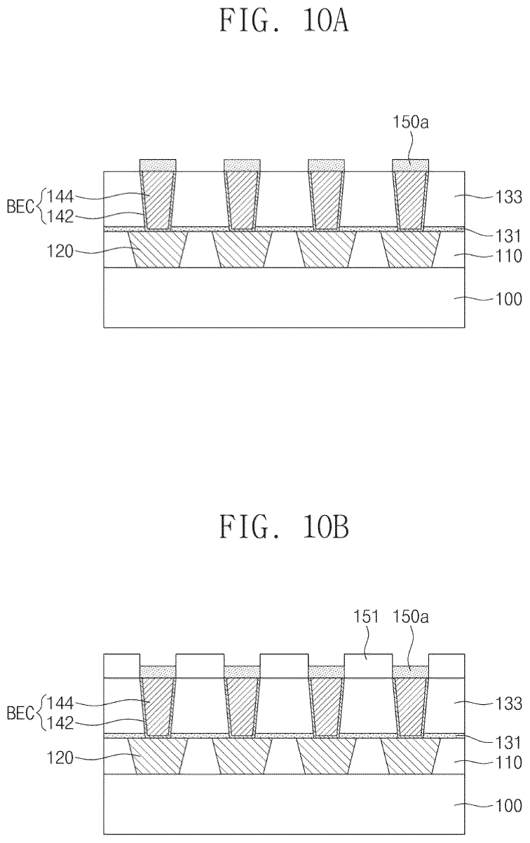

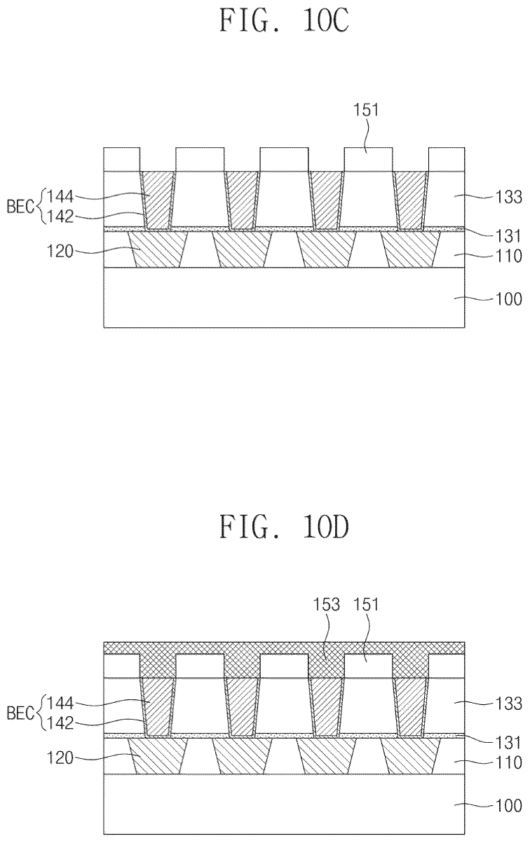

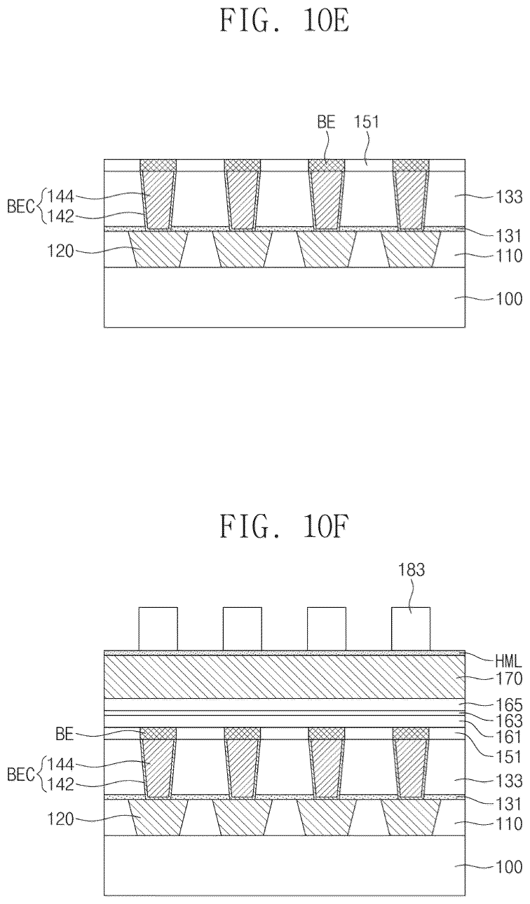

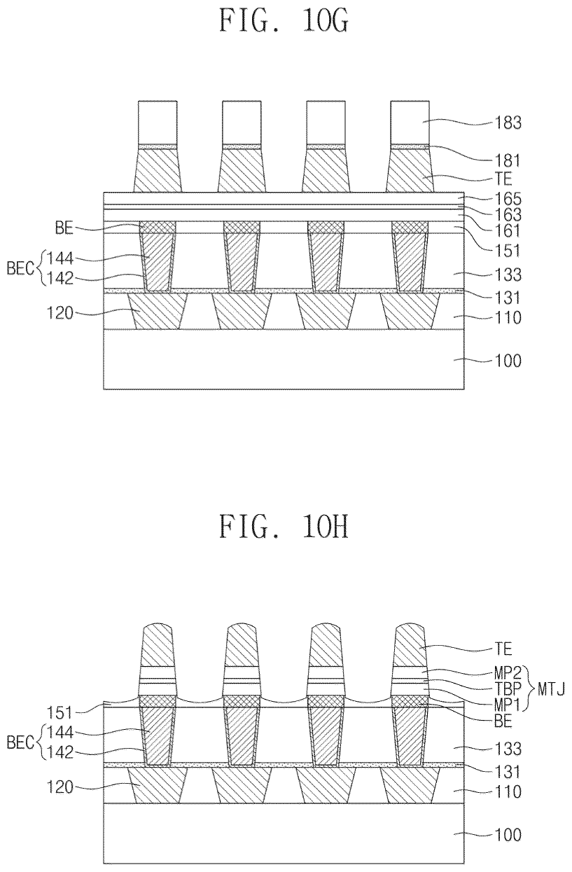

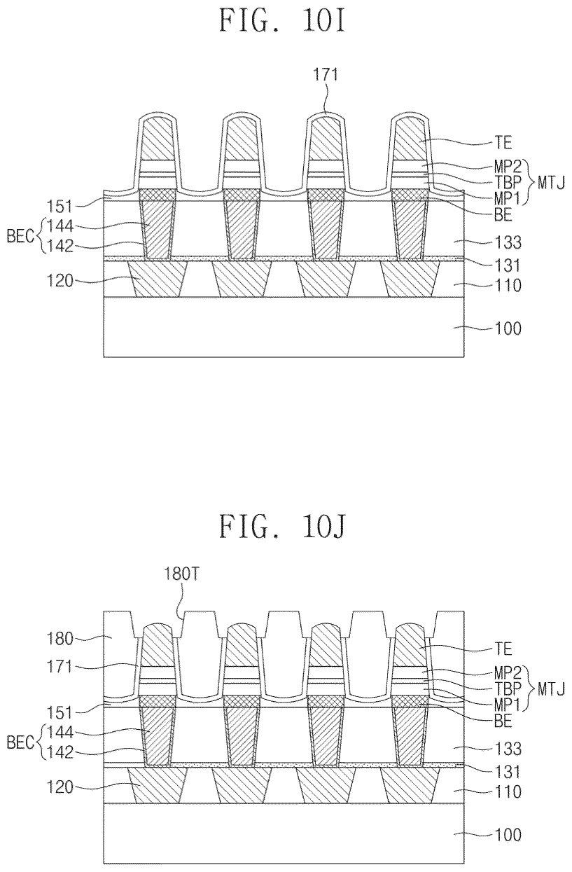

FIGS. 10A to 10J are drawings for illustrating a method of manufacturing a semiconductor memory device according to one or more embodiments, and are cross-sections taken along the line I-I′ of FIG. 3.

Referring to FIG. 10A, a first interlayer insulating layer 110 may be formed on a substrate 100.

The substrate 100 may be a silicon substrate, a Ge substrate, and/or a Si—Ge substrate. Selection transistors may be formed on the substrate 100 as the selection elements SE described with reference to FIG. 2.

The first interlayer insulating layer 110 may be formed to cover the selection elements. The first interlayer insulating layer 110 may be formed as a single layer or multiple layers including oxide, nitride, and/or oxynitride. The first interlayer insulating layer 110 may include an insulating material. For example, the first interlayer insulating layer 110 may be formed of an HDP oxide layer, a TEOS layer, a PE-TEOS layer, a USG layer, a BSG layer, a PSG layer, a BPSG layer, a SOG layer, a TOSZ layer, or a combination thereof. The first interlayer insulating layer 110 may be formed, for example, through a physical vapor deposition process or a chemical vapor deposition process.

Lower wiring lines 120 may be vertically stacked in the first interlayer insulating layer 110. The lower wiring lines 120 may include via portions and wiring portions. The lower wiring lines 120 may be electrically connected to selection elements. The lower wiring lines 120 may include, for example, Cu or a Cu alloy. Here, the Cu alloy refers to copper mixed with a small amount of C, Ag, Co, Ta, In, Sn, Zn, Mn, Ti, Mg, Cr, Ge, Sr, Pt, Mg, Al, or Zr. As another example, the lower wiring lines 120 may include, for example, a metal such as W, Ti, and Ta, and/or a conductive metal nitride such as TiN, TaN, and WN.

A diffusion barrier layer 131 may be formed on upper surfaces of the lower wiring lines 120 and the first interlayer insulating layer 110. The diffusion barrier layer 131 may be formed of, for example, SiN, SiON, SiC, SiCN, and combinations thereof.

A second interlayer insulating layer 133 may be formed on the diffusion barrier layer 131. The second interlayer insulating layer 133 may be formed of an HDP oxide layer, a TEOS layer, a PE-TEOS layer, a USG layer, a BSG layer, a PSG layer, a BPSG layer, a SOG layer, a TOSZ layer, or a combination thereof. As another example, the second interlayer insulating layer 133 may be formed of a dielectric material having a lower dielectric constant than that of the silicon oxide layer.

Subsequently, lower contact plugs BEC may be formed to penetrate the second interlayer insulating layer 133 and the diffusion barrier layer 131 and to be connected to the lower wiring lines 120.

The lower contact plugs BEC may be formed to be spaced apart from each other on the substrate 100 when viewed in a top plan view. Forming the lower contact plugs BEC may include forming lower contact holes penetrating the second interlayer insulating layer 133, sequentially depositing a barrier metal layer and a metal layer on the second interlayer insulating layer 133 having the lower contact holes, and performing a planarization process on the barrier metal layer and the metal layer.

The barrier metal layer and the metal layer may be formed using a layer-forming technique having excellent step coverage, such as chemical vapor deposition (CVD), physical vapor deposition (PVD), or atomic layer deposition (ALD). The barrier metal layer may conformally be provided on and cover an upper surface of the second interlayer insulating layer 133 and inner walls of the lower contact holes. The metal layer may be deposited to completely fill the lower contact holes where the barrier metal layer is formed.

A planarization process may be performed on the barrier metal layer and the metal layer to form barrier metal patterns 142 and metal patterns 144 in the lower contact holes.

A chemical mechanical polishing (CMP) process and an etch-back process may be used as a planarization process for the barrier metal layer and the metal layer. Upper surfaces of the metal patterns 144 may be substantially coplanar with an upper surface of the second interlayer insulating layer 133 by the planarization process.

Each of the lower contact plugs BEC formed as described above may include a barrier metal pattern 142 and a metal pattern 144. The lower contact plugs BEC may include a metal material different from the metal material in the lower wiring lines 120. The lower contact plugs BEC may include, for example, a metal such as W, Ti, Ta, and Cu, and/or a conductive metal nitride such as TiN, TaN, and WN.

In one example, the metal pattern 144 may include a metal, and the barrier metal pattern 142 may include a conductive metal nitride. The barrier metal pattern 142 may include, for example, a conductive metal nitride such as TiN, TaN, and WN. The metal pattern 144 may include, for example, a metal material such as W, Ti, and Ta. For example, the barrier metal pattern 142 may be a TiN layer, and the metal pattern 144 may be a W layer.

Continuing with reference to FIGS. 10A and 10B, lower electrodes BE may be formed on upper surfaces of lower contact plugs BEC using an area-selective deposition (ADS) process.

For example, referring to FIG. 10A, first, a deposition inhibition layer 150a may be formed on upper surfaces of lower contact plugs BEC.

The deposition inhibition layer 150a may include atoms that bind to functional groups on the surface of the lower contact plugs BEC made of a metal material. In one or more embodiments, the deposition inhibition layer 150a may include an oxygen inhibitor. The deposition inhibition layer 150a may be formed by adsorbing the oxygen inhibitor to the upper surfaces of the lower contact plugs BEC. For example, the deposition inhibition layer 150a may include Pt, W, Co, Ru, Pd, Ir, or Ag.

Referring to FIG. 10B, after forming the deposition inhibition layer 150a, a deposition process may be performed to form a buffer insulating layer 151 on the upper surface of the second interlayer insulating layer 133.

The buffer insulating layer 151 may be selectively deposited on a surface of the second interlayer insulating layer 133 by performing an atomic layer deposition process. When depositing the buffer insulating layer 151, the deposition inhibition layer 150a may be formed on the lower contact plugs BEC, thereby selectively depositing the buffer insulating layer 151 only on the upper surface of the second interlayer insulating layer 133. The buffer insulating layer 151 may include a metal oxide, and may include, for example, ZnO, Al₂O₃, HfO₂, TiO₂, or ZrO₂. The buffer insulating layer 151 may be deposited thicker than the deposition inhibition layer 150a.

Referring to FIG. 10C, the deposition inhibition layer 150a may be removed to expose the upper surfaces of the lower contact plugs BEC. The deposition inhibition layer 150a may be provided using an etching recipe having etching selectivity with respect to the buffer insulating layer 151 and the lower contact plugs BEC.

By removing the deposition inhibition layer 150a, the buffer insulating layer 151 may have openings exposing the upper surfaces of the lower contact plugs BEC. Sidewalls of the buffer insulating layer 151 may be aligned with sidewalls of the lower contact plugs BEC.

Referring to FIG. 10D, a lower electrode layer 153 may be deposited on the lower contact plugs BEC and the buffer insulating layer 151.

The lower electrode layer 153 may completely fill the openings formed in the buffer insulating layer 151. The lower electrode layer 153 may be formed, for example, by a chemical vapor deposition process, an atomic layer deposition process, or a physical vapor deposition process. The lower electrode layer 153 may include, for example, a conductive metal nitride, such as TiN and/or TaN. As another example, the lower electrode layer 153 may include a metal such as Pt, W, Co, Ru, Pd, Ir, or Ag.

Referring to FIG. 10E, a planarization process may be performed on the lower electrode layer 153 to form lower electrodes BE.

For example, a chemical mechanical polishing (CMP) process and an etch-back process may be used as the planarization process. By the planarization process, upper surfaces of the lower electrodes BE may be substantially coplanar with an upper surface of the buffer insulating layer 151. The lower electrodes BE may be spaced apart from each other by the buffer insulating layer 151. Sidewalls of the lower electrodes BE may be in direct contact with the buffer insulating layer 151.

Referring to FIG. 10F, a first magnetic layer 161, a tunnel barrier layer 163, and a second magnetic layer 165 may be sequentially stacked on the lower electrodes BE and the buffer insulating layer 151. Each of the first magnetic layer 161 and the second magnetic layer 165 may include at least one magnetic layer. Each of the first magnetic layer 161, the tunnel barrier layer 163, and the second magnetic layer 165 may be formed by, for example, a physical vapor deposition method or a chemical vapor deposition method.

The first magnetic layer 161, the tunnel barrier layer 163, and the second magnetic layer 165 may include the same material as that of the first magnetic pattern MP1, the tunnel barrier pattern TBP, and the second magnetic pattern MP2 described with reference to FIGS. 9A and 9B, respectively.

Thereafter, an upper electrode layer 170 and a hard mask layer HML may be sequentially formed on the second magnetic layer 165.

The upper electrode layer 170 may include at least one of a metal (e.g., Ta, W, Ru, Ir, etc.) and a conductive metal nitride (e.g., TiN). The upper electrode layer 170 may be formed by a sputtering, chemical vapor deposition, or atomic layer deposition process.

The hard mask layer HML may include, for example, SiN and/or SiON. The hard mask layer HML may be formed by a sputtering, chemical vapor deposition, or atomic layer deposition process.

A thickness of the upper electrode layer 170 may be greater than a thickness of the lower electrodes BE, and a thickness of the hard mask layer HML may be smaller than the thickness of the upper electrode layer 170.

Upper mask patterns 183 may be formed on the hard mask layer HML. The upper mask patterns 183 may define regions where magnetic tunnel junction patterns to be described later are to be formed. For example, the upper mask patterns 183 may be spaced apart from each other when viewed in a plan view. The upper mask patterns 183 may be formed by depositing the upper mask layer on the hard mask layer HML and then performing a patterning process on the upper mask layer. The upper mask patterns 183 may be formed of an insulating material of the silicon oxide series, for example. A thickness of the upper mask patterns 183 may be greater than a thickness of the hard mask layer HML.

Referring to FIG. 10G, the hard mask layer HML may be etched using the upper mask patterns 183 as an etching mask to form hard mask patterns 181 on the upper electrode layer 170. Subsequently, the upper electrode layer 170 may be etched using the upper mask patterns 183 and the hard mask patterns 181 as an etching mask. Accordingly, upper electrodes TE may be formed on the second magnetic layer 165.

Referring to FIG. 10H, an ion beam etching process using the upper electrodes TE as an etching mask may be performed to form magnetic tunnel junction patterns MTJ. Each of the magnetic tunnel junction patterns MTJ may include a first magnetic pattern MP1, a tunnel barrier pattern TBP, and a second magnetic pattern MP2 sequentially stacked on each of the lower electrodes BE.

The ion beam etching process may be performed by irradiating (emitting) an ion beam onto the substrate 100. The ion beam may be irradiated (emitted) at a certain angle with respect to the upper surface of the substrate 100. The ion beam may include an inert ion (e.g., an argon cation (Ar⁺)). During the ion beam etching process, the substrate 100 may rotate around a rotation axis perpendicular to the upper surface of the substrate 100.

According to one or more embodiments, during the ion beam etching process for forming magnetic tunnel junction patterns MTJ, the buffer insulating layer 151 between the lower electrodes BE may be exposed.

The ion beam etching process may sequentially etch the second magnetic layer 165, the tunnel barrier layer 163, and the first magnetic layer 161. An upper surface of the buffer insulating layer 151 exposed by the ion beam etching process may be rounded or recessed.

According to one or more embodiments, as the lower electrodes are formed in advance, the ion beam etching process conditions may be reduced. As the etching of the lower electrodes is not performed during the ion beam etching process, the second interlayer insulating layer 133 between the lower contact plugs may be prevented from being exposed. Therefore, the second interlayer insulating layer 133 may be prevented from being etched during the ion beam etching process, and the lower wiring lines 120 may be prevented from being damaged.

An etching depth may be reduced during the ion beam etching process, thereby reducing shadowing effect that interferes with movement of ion beams provided as an etching source by the mask pattern. In addition, ion beam etching process time may be reduced.

In addition, as the lower electrodes are not etched during the ion beam etching process, generation of byproducts from the lower electrodes may be prevented. Therefore, an electrical short or current leakage phenomenon between the lower electrodes may be prevented.

Referring to FIG. 10I, a capping insulating layer 171 provided on and covering the upper electrodes TE and the magnetic tunnel junction patterns MTJ may be formed. The capping insulating layer 171 may conformally be provided on and cover side surfaces of the upper electrodes TE and side surfaces of the magnetic tunnel junction patterns MTJ. For example, the capping insulating layer 171 may extend onto an upper surface of the buffer insulating layer 151 between the magnetic tunnel junction patterns MTJ. The capping insulating layer 171 may include a nitride (e.g., SiN).

Referring to FIG. 10J, after forming the capping insulating layer 171, a buried insulating layer 180 may be formed on the entire surface of the substrate 100. According to one or more embodiments, the buried insulating layer 180 may include a plurality of insulating layers stacked on the capping insulating layer 171.

The buried insulating layer 180 may include, for example, silicon oxide or a low-k dielectric material having a dielectric constant lower than a dielectric constant of silicon oxide. In addition, the buried insulating layer 180 may include, for example, SiN, SiON, SiC, SiCN, and combinations thereof.

The buried insulating layer 180 may fill a space between the magnetic tunnel junction patterns MTJ and may cover the upper electrodes TE.

The buried insulating layer 180 may be patterned to form contact holes 180T that expose the upper electrodes TE, respectively. When forming the contact holes 180T, portions of the capping insulating layer 171 provided on and covering the upper surfaces of the upper electrodes TE may be etched.

Thereafter, referring to FIG. 4, conductive contacts 185 may be formed in the contact holes 180T of the buried insulating layer 180. The conductive contacts 185 may be connected to the upper electrodes TE, respectively.

Forming the conductive contacts 185 may include forming a conductive layer that fills the contact holes on the buried insulating layer 180, and planarizing the conductive layer until the buried insulating layer 180 is exposed.

Then, an etching stop layer 191 that is provided on and covers the upper surfaces of the conductive contacts 185 on the buried insulating layer 180 may be formed, and a mold layer 193 may be formed on the etching stop layer 191.

Bit lines BL may be formed in the etching stop layer 191 and the mold layer 193. Forming the bit lines BL may include forming trenches penetrating the mold layer 193 and the etching stop layer 191, forming a barrier metal layer conformally provided on and covering inner walls of the trenches, forming a metal layer completely filling the trenches in which the barrier metal layer is formed, and planarizing the barrier metal layer and the metal layer to expose an upper surface of the mold layer 193. For example, the trenches may extend in the second direction D2 and may be spaced apart from each other in the first direction D1. Each of the trenches may expose the conductive contacts 185 arranged in the second direction D2 among the conductive contacts 185. Accordingly, each of the bit lines BL may be commonly connected to the conductive contacts 185 arranged in the second direction D2.

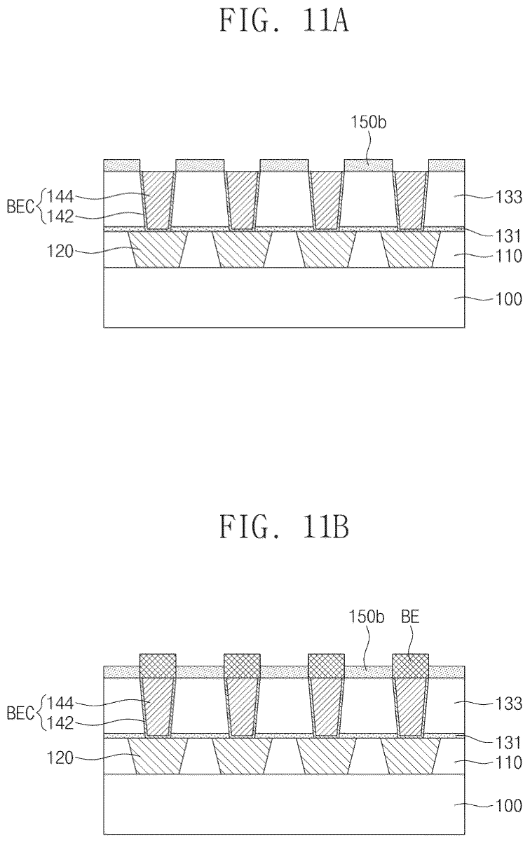

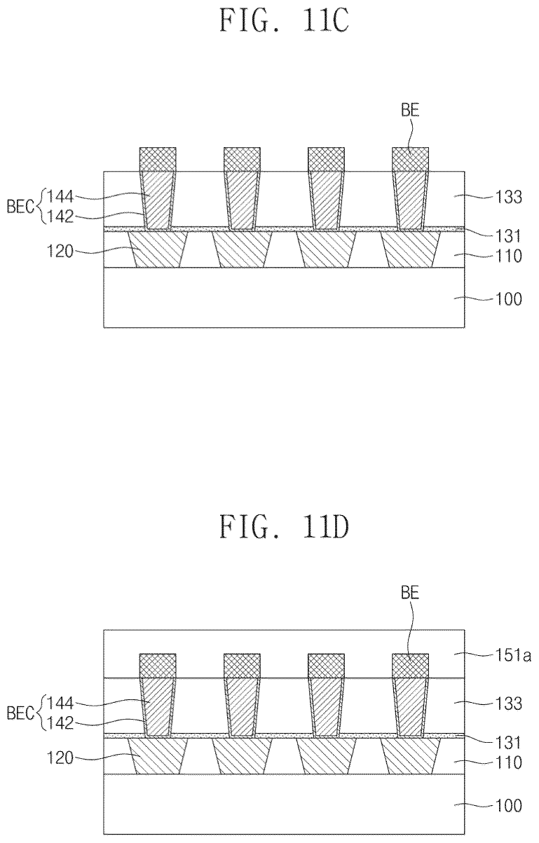

FIGS. 11A, 11B, 11C, and 11D are sectional views taken long line I-I′ of FIG. 3 to illustrate a method for manufacturing a semiconductor memory device according to one or more embodiments.

For simplicity of explanation, descriptions of technical features identical to those of the method for manufacturing a semiconductor memory device described above with reference to FIGS. 10A to 10J may be omitted, and differences between the embodiments will be described.

Referring to FIG. 11A, when performing an area-selective deposition (ADS) process to form the lower electrodes BE, a deposition inhibition layer 150b may first be formed on the upper surface of the second interlayer insulating layer 133. For example, the deposition inhibition layer 150b may include atoms that bind to functional groups on a surface of the second interlayer insulating layer 133 formed of an insulating material. The deposition inhibition layer 150b may include a metal inhibitor. The deposition inhibition layer 150b may be formed by adsorbing a metal suppressor onto the upper surfaces of the second interlayer insulating layer 133. For example, the deposition inhibition layer 150b may include silicon oxide, etc.

Referring to FIG. 11B, after the deposition inhibition layer 150b is formed, a deposition process may be performed so that the lower electrodes BE may be selectively deposited on the upper surfaces of the lower contact plugs BEC, respectively.

The lower electrodes BE may be selectively deposited on the surfaces of the lower contact plugs BEC by performing an atomic layer deposition process. When the lower electrodes BE are formed, the deposition inhibition layer 150b may be formed on the upper surface of the second interlayer insulating layer 133, thereby selectively depositing the lower electrodes BE only on the upper surfaces of the lower contact plugs BEC. The lower electrodes BE may include, for example, Pt, W, Co, Ru, Pd, Ir, or Ag.

Referring to FIG. 11C, the deposition inhibition layer 150b may be removed to expose the upper surface of the second interlayer insulating layer 133. As the deposition inhibition layer 150b is removed, the sidewalls of the lower electrodes BE may be exposed.

Referring to FIG. 11D, a preliminary buffer insulating layer 151a may be formed on the upper surface of the second interlayer insulating layer 133 and the lower electrodes BE. The preliminary buffer insulating layer 151a may be deposited on the entire surface of the substrate 100 by performing a chemical vapor deposition process or an atomic layer deposition process.

Subsequently, a planarization process may be performed on the preliminary buffer insulating layer 151a so that the upper surfaces of the lower electrodes BE are exposed. Accordingly, as described with reference to FIG. 10E, the buffer insulating layer 151 may be formed between the lower electrodes BE. The upper surface of the buffer insulating layer 151 may be substantially coplanar with the upper surfaces of the lower electrodes BE.

Thereafter, as described with reference to FIGS. 10F to 10J, magnetic tunnel junction patterns, upper electrodes, conductive contacts, and bit lines may be formed on the lower electrodes BE.

According to some one or more embodiments, the lower electrodes may be separated from each other before depositing the magnetic tunnel junction layer, thereby alleviating the intensity of the ion beam during etching process for patterning the magnetic tunnel junction layer. In addition, the recessed amount of the interlayer insulating layer between the lower wiring lines may be reduced, thereby preventing the lower wiring lines from being damaged.

Furthermore, the thickness of the lower electrode may be reduced, thereby reducing the shadowing effect, which interferes with the movement of the ion beams provided as etching sources by the mask pattern during patterning the magnetic tunnel junction layer. The manufacturing process time of the semiconductor memory device may be reduced, thereby improving the process margin.

While embodiments have been described with reference to the figures, it will be understood by those of ordinary skill in the art that various changes in form and details may be made therein without departing from the spirit and scope as defined by the following claims and their equivalents.

What is claimed is:

1. A semiconductor memory device comprising:
a substrate;
an interlayer insulating layer on the substrate;
lower contact plugs penetrating the interlayer insulating layer;
magnetic tunnel junction patterns on the lower contact plugs, respectively;
lower electrodes between the lower contact plugs and the magnetic tunnel junction patterns, respectively;
a buffer insulating layer between the lower electrodes and on the interlayer insulating layer;
a capping insulating layer on a sidewall of each of the magnetic tunnel junction patterns and an upper surface of the buffer insulating layer; and
upper electrodes on the magnetic tunnel junction patterns, respectively.

2. The semiconductor memory device of claim 1, wherein a lower surface of the capping insulating layer is at a level between an upper surface of each of the lower electrodes and a lower surface of each of the lower electrodes.

3. The semiconductor memory device of claim 1, wherein the buffer insulating layer has a rounded upper surface.

4. The semiconductor memory device of claim 1, wherein a sidewall of each of the lower electrodes is aligned with a sidewall of each of the lower contact plugs.

5. The semiconductor memory device of claim 1, wherein a sidewall of each of the lower electrodes is spaced apart from the sidewall of each of the magnetic tunnel junction patterns.

6. The semiconductor memory device of claim 1, wherein a lower surface of each of the lower electrodes is a first width and is in contact with an upper surface of each of the lower contact plugs, and
wherein an upper surface of each of the lower electrodes is a second width and in contact with a lower surface of each of the magnetic tunnel junction patterns, and
wherein the first width is greater than the second width.

7. The semiconductor memory device of claim 1, wherein a center of each of the lower electrodes has a first thickness, and an edge of each of the lower electrodes has a second thickness, and
wherein the second thickness is smaller than the first thickness.

8. The semiconductor memory device of claim 1, wherein each of the lower electrodes comprises an upper portion in contact with each of the magnetic tunnel junction patterns and a lower portion in contact with each of the lower contact plugs,
wherein the lower portion of each of the lower electrodes has a first sidewall aligned with a sidewall of each of the lower contact plugs, and
wherein the upper portion of each of the lower electrodes has a second sidewall aligned with the sidewall of each of the magnetic tunnel junction patterns.

9. The semiconductor memory device of claim 1, wherein the capping insulating layer is spaced apart from the interlayer insulating layer.

10. A semiconductor memory device comprising:
a substrate;
an interlayer insulating layer;
a lower contact plug penetrating the interlayer insulating layer;
a magnetic tunnel junction pattern connected to the lower contact plug;
a lower electrode between the lower contact plug and the magnetic tunnel junction pattern; and
an upper electrode on the magnetic tunnel junction pattern,
wherein a first sidewall of the lower electrode is aligned with a sidewall of the lower contact plug and is spaced part from a sidewall of the magnetic tunnel junction pattern.

11. The semiconductor memory device of claim 10, wherein the lower electrode comprises a lower portion in contact with an upper surface of the lower contact plug and comprising the first sidewall, and the lower electrode comprises an upper portion in contact with a lower surface of the magnetic tunnel junction pattern, and
wherein the upper portion of the lower electrode has a second sidewall that is aligned with the sidewall of the magnetic tunnel junction pattern.

12. The semiconductor memory device of claim 10, wherein a width of a lower surface of the magnetic tunnel junction pattern is smaller than a width of a lower surface of the lower electrode.

13. The semiconductor memory device of claim 10, further comprising a buffer insulating layer on the first sidewall of the lower electrode on the interlayer insulating layer.

14. The semiconductor memory device of claim 13, wherein the buffer insulating layer has a rounded upper surface.

15. The semiconductor memory device of claim 13, wherein the buffer insulating layer comprises a metal element and oxygen.

16. The semiconductor memory device of claim 10, wherein a center of the lower electrode has a first thickness and an edge of the lower electrode has a second thickness smaller than the first thickness.

17. A semiconductor memory device comprising:
a substrate;
lower wiring lines on the substrate;
an interlayer insulating layer on the lower wiring lines;
lower contact plugs penetrating the interlayer insulating layer;
magnetic tunnel junction patterns on the lower contact plugs, respectively;
lower electrodes between the lower contact plugs and the magnetic tunnel junction patterns, respectively;
a buffer insulating layer between the lower electrodes on the interlayer insulating layer;
upper electrodes on the magnetic tunnel junction patterns, respectively;
a capping insulating layer on a sidewall of each of the magnetic tunnel junction patterns and an upper surface of the buffer insulating layer;
a buried insulating layer on the magnetic tunnel junction patterns on the capping insulating layer; and
bit lines penetrating the buried insulating layer and connected to the upper electrodes,
wherein the capping insulating layer is spaced apart from an upper surface of the interlayer insulating layer.

18. The semiconductor memory device of claim 17, wherein a lower surface of the capping insulating layer is at a level between an upper surface of each of the lower electrodes and a lower surface of each of the lower electrodes.

19. The semiconductor memory device of claim 17, wherein a sidewall of each of the lower electrodes is aligned with a sidewall of each of the lower contact plugs.

20. The semiconductor memory device of claim 17, wherein a sidewall of each of the lower electrodes has a first thickness and the upper surface of each of the lower contact plugs has a second thickness that is greater than the first thickness.
